(19) United States
(12) Patent Application Publication
(10) Pub. No.: US 2005/0067740 A1
(43) Pub. Date: Mar. 31, 2005

(54) Wafer defect reduction by short pulse laser ablation

(76) Inventor: Frederick Haubensak, Los Altos, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/674,372

(22) Filed: Sep. 29, 2003

(51) Int. Cl. H01L 21/26

(52) U.S. Cl. 264/400; 438/940

(57) ABSTRACT

A method and apparatus to focus a short pulse laser beam onto a particle defect on a wafer surface, then ablate, or explosively evaporate, the particle defect with the short pulse laser beam.

### FIELD

The present invention relates generally to the field of semiconductor technology and, more specifically, to removal of particle defects on a wafer.

### BACKGROUND

Semiconductor circuits are typically created by a multitude of procedures and techniques. For example, one conventional process of forming integrated circuits may begin by forming layers of material on a semiconductor substrate, or wafer 100, as illustrated in FIG. 1A. Then, according to a multitude of techniques, the layers of material may then be “patterned” into electronic structures, such as 115 in FIG. 1B, (transistors, capacitors, etc.), on the wafer surface 110. Insulator layers may then be formed over the electronic structures. The insulator layers may also be “patterned” to have various types of holes and channels which are then filled to form metallic interconnections between many of the electronic structures and also to external input/output devices.

As illustrated in FIG. 1B, during the “patterning” processes, various particles 120 of material may undesirably form upon a one or more surfaces 110 of the wafer 100. These undesirable particles may be the direct result of etching processes that etch the layers of material into small particles that tend to undesirably settle upon the wafer surface. One current method of removing the undesirable particles is illustrated in FIG. 1C. In FIG. 1C, a cassette of wafers 130 is immersed in a liquid cleaning solution bath 140 and performing wet cleaning techniques to wash away the undesirable particles. However, the chemicals used to wet clean the wafer are often harsh chemicals that can cause damage to certain materials that are used to form the electronic structures. FIG. 1D illustrates a layer of material 150 and a structure 115 that have been immersed in the harsh chemicals and have been damaged. Once damaged, the electronic circuitry may suffer performance problems, even resulting in total failure. Therefore, there are times during the fabrication process when the wafer should not be immersed in liquid chemicals. As a result, the undesirable particles (i.e., “particle defects”), must remain on the wafer surface. If additional layers are formed without first removing the particle defects, the resulting layers and structures may consequently be non-planar, or in other ways malformed. Additionally, even if used, a wet cleaning process may not entirely remove all of the particles. Consequently, in the current state-of-art, particle defects, between the sizes of about 1 to 10 um, are many times left on wafer surfaces and, unfortunately, become a part of the electronic circuitry. Though small, and somewhat tolerable, these particle defects can cumulatively result in noticeable effects on circuit performance. Without a way of removing these particle defects, skilled artisans have merely left the particle defects in place and designed the circuitry according to a tolerance factor for the particle defects. Therefore, the conventional process described would require that the integrated circuit be designed with a certain degree of tolerance for particle defects that could not be chemically removed.

### BRIEF DESCRIPTION OF THE DRAWINGS

Embodiments of the present invention are illustrated by way of example and should not be limited by the figures of the accompanying drawings in which like references indicate similar elements and in which:

FIGS. 1A-1D illustrate the prior art process of removing particle defects from a wafer.

FIGS. 2A-2D illustrate laser ablation of a particle defect on a wafer.

FIG. 3 illustrates a method of focusing a laser beam according to one embodiment of the invention.

FIGS. 4A-4G illustrate a system used for the detection and ablation of a particle defect.

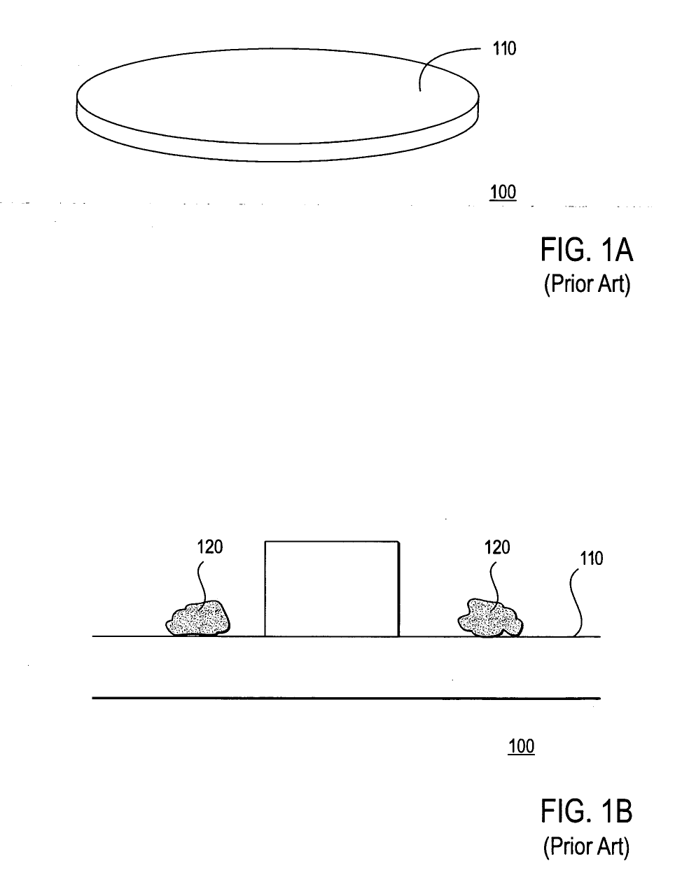

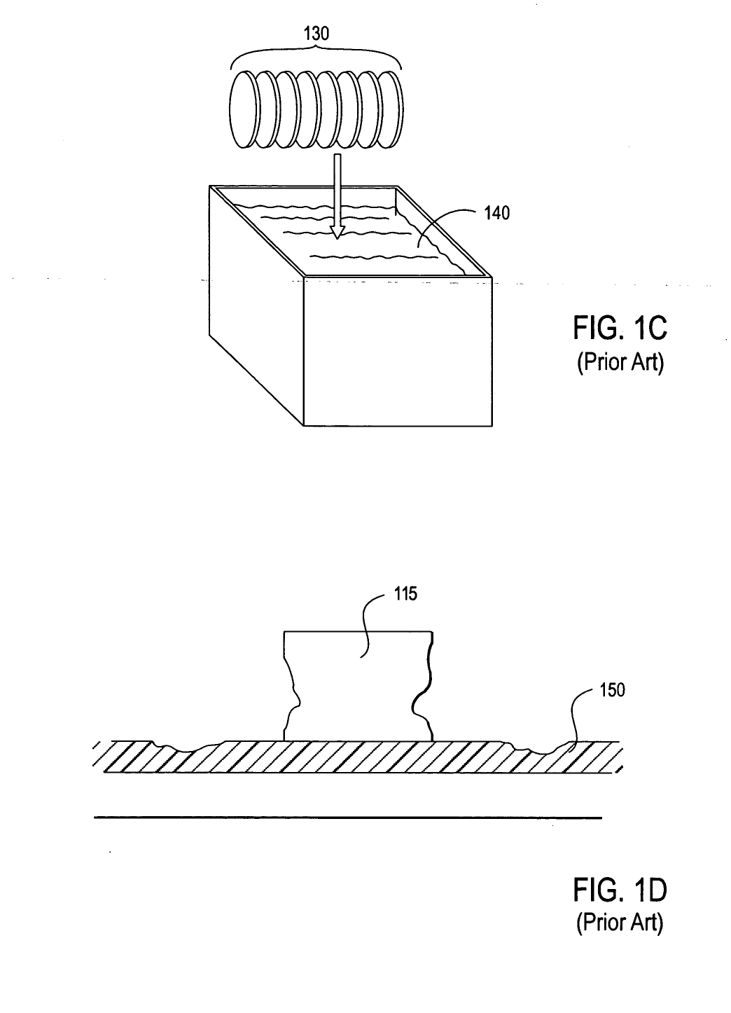

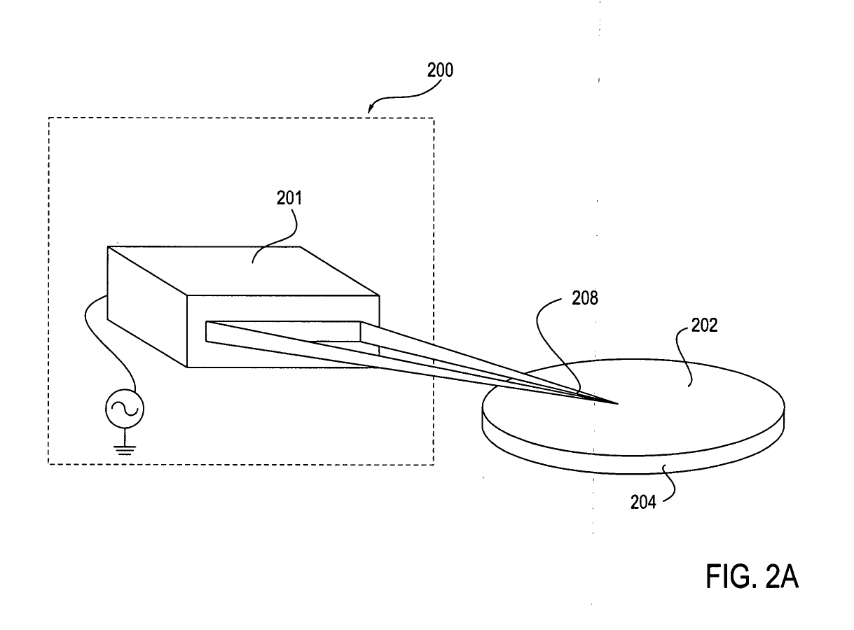

### DETAILED DESCRIPTION

Described herein is a method and apparatus to reduce wafer defects by short pulse laser ablation. In the following description numerous specific details are set forth. One of ordinary skill in the art, however, will appreciate that these specific details are not necessary to practice embodiments of the invention. While certain exemplary embodiments of the invention are described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art. In other instances well known semiconductor fabrication processes, techniques, materials, equipment, etc., have not been set forth in particular detail in order to not unnecessarily obscure embodiments of the present invention.

Described herein is a method and apparatus to focus a short pulse laser beam onto a particle defect on a wafer surface, then ablate, or explosively evaporate, the particle defect with the short pulse laser beam. According to one embodiment of the invention a femtosecond laser may be utilized to produce a laser beam having a very short time-pulsed frequency, in the femtosecond range. Additionally, the laser beam may be operated at a high energy density. The short time-pulse and the high energy combine to produce an explosive evaporation, or ablation, of the particle defect, that obliterates the particle defect but does not significantly affect the underlying wafer surface. Consequently, particle defects may be removed from the wafer surface without having to immerse the wafer in a chemical cleaning solution.

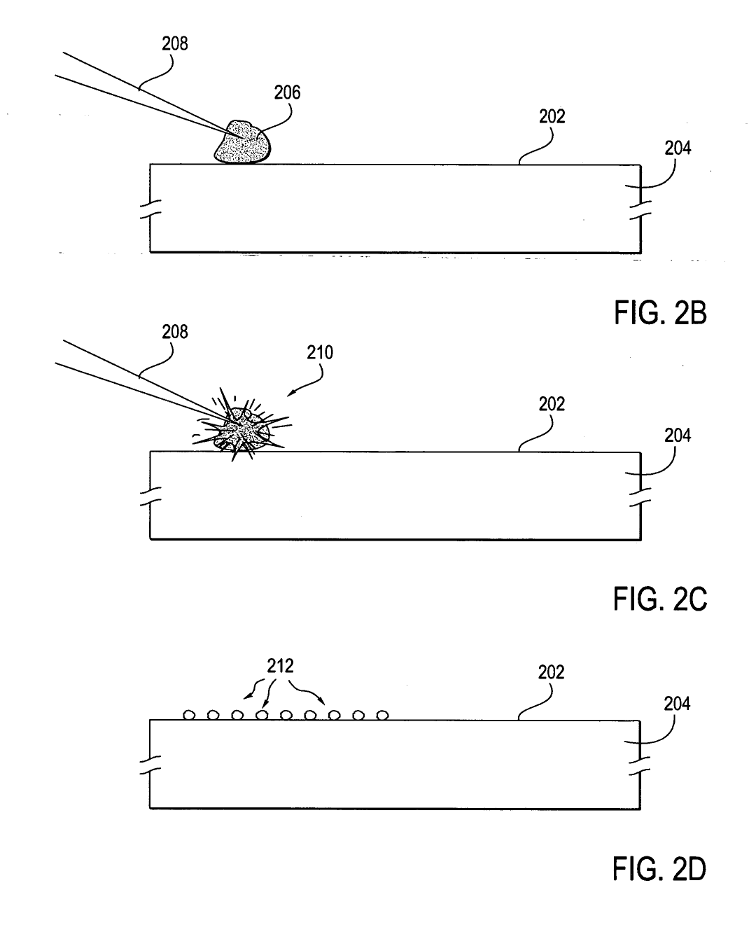

FIGS. 2A-2D illustrate an apparatus 200, according to one embodiment of the invention. The apparatus 200 includes a short pulse laser 201 to remove particle defects on a surface 202 of a wafer 204. As described herein, the term “wafer surface” may mean a surface of a wafer substrate or a surface of any layer or structure that is overlying the wafer substrate. The wafer substrate may include one or more conductive, semiconductive, or insulative materials.

The short pulse laser 201, in one embodiment of the invention, may be a femtosecond laser. A femtosecond laser is a laser that is operated with a time frequency pulse within the femtosecond range. In one embodiment of the invention, the time frequency range of the pulse period may be approximately between about 50 femtoseconds (fs) to about 500 fs, preferably about 200 fs. According to one embodiment of the invention, the short pulse laser 201 may also be operated with a relatively high energy, between about 1 to about 30 microjoules per pulse. The short pulse and high energy of the short pulse laser beam 208 contribute to an ablation effect on the particle defect. Ablation is described in further detail below in conjunction with FIG. 2B.

FIG. 2B illustrates an ablation procedure as performed by the short pulse laser 201 of FIG. 2A. Referring to FIG. 2B, a particle defect 206 may exist on a wafer 204 surface 202. Particle defects may be formed from layers of materials on a wafer surface 202 that have been etched or otherwise broken down into small particles as a result of a typical wafer-fabrication processing procedure. These small particles undesirably settle onto existing surfaces of the wafer and may be termed “defects” because their presence has no specific purpose in the overall wafer design. The particles may even cause an undesirable reduction of electronic performance of an integrated circuit. The particle defects such as 206 may include materials that are utilized in the fabrication of electronic circuits and integrated circuitry formed on the wafer 204. Some materials may include Fe, Cr, Ni, Si, or compounds such as SiO₂ or SiN.

The particle defects may vary in size, for example, having an approximate diameter of between about 1 micrometers (μm) to about 10 μm. Particle defects, as described herein, are distinguished from other types of defects known as “embedded defects”. For example, a particle defect 206 as described herein has a significant portion of its volume above the wafer surface 202, or in other words, a portion that is not significantly embedded into the wafer surface 202. A particle defect 206, therefore, as described herein may further be described as a “non-embedded” particle, a “free-standing” particle, or any other similar term that conveys the meaning that a significant volume of between 75-100% of the particle defect 206 is separate in morphology from the underlying material of the wafer surface 202.

Non-embedded particle defects, according to embodiments of the invention, may be removed by the short pulse laser 201 without significant damage to the wafer surface 202. For instance, the explosive nature of ablation may cause damage to the wafer surface 202 if the particle were to have a significant portion of its mass embedded within the wafer surface 202. However, the explosive nature of ablation will not cause significant damage to the wafer surface 202 since the particle defect and the underlying wafer surface 202 are distinctly separate in morphology. As a result, the wafer surface 202 can maintain its designed shape, whether planar (as shown), or otherwise shaped, according to the desired design of the wafer surface 202 and/or surrounding structures.

The apparatus 200 of FIG. 2A can be utilized to direct a short pulse, high energy laser beam onto a particle defect to ablate the particle defect. Ablation is defined herein as the process of directing the laser beam onto the particle defect then pulsing the laser beam, in the femtosecond pulse range, so that the laser pulse 208 strikes the particle and heats the particle to a very high temperature, in a very short period of time, causing evaporation and fragmentation of the particle 206 to occur almost simultaneously, as shown in FIG. 2C, thus causing the particle defect 206 to undergo explosive evaporation 210. In other words, ablating causes the thermal gradient in the particle defect to increase rapidly and create substantial internal stress that causes the particle defect to vaporize 210.

The laser beam may be pulsed at a very short time period (i.e., femtosecond range), in rapid succession. The very rapid, short pulses, carry significant amounts of energy and tend to excite atoms within the particle very quickly. Pulses that are too long in duration, above about 500 fs, may result in less effective ablation. Pulses in the nanosecond range (beyond 1000 fs) may not result in ablation at all and may heat the particle defect too slowly, thus resulting in a significant transfer of thermal energy to the underlying wafer surface 202 that may result in significant damage to the underlying wafer surface 202. In some cases the particle may heat too slowly, causing a melting effect instead of an explosive effect within the particle. If this occurs, the particle may not be effectively reduced to insignificant amounts or significant damage may occur to the underlying wafer surface 202. On the other hand, pulses that are too short in duration, lower than about 1 fs, are practically difficult to achieve and lose their monochromatic nature.

Another embodiment of the invention includes operating the short pulse laser 201 at a “high” energy in additional to operating the short pulse laser 201 at within a femtosecond range. The term “high” is a relative term, and may be determined by taking into account the size of the particles to be ablated as well as power delivered to the laser. In one embodiment of the invention, for particles ranging in the size of approximately 1 um to about 10 um, a relatively high energy is about 1 uJ to about 30 uJ. Hence, according to one embodiment of the invention, an energy density for a large particle would be approximately 30 J/cm² for 200 fs. Hence, in one embodiment of the invention, the laser may be said to be operated at 30 J/cm², a relatively high energy for the small particle defects, but effective at causing ablation.

The end result, as shown in FIG. 2D, is the disintegration of the particle into much smaller sized pieces 212 that are negligible to design tolerances. Additionally, the surface 202 of the wafer 204 remains significantly as originally formed. In FIG. 2D, the surface 202 remains relatively planar and essentially no damage has occurred to the surface 202.

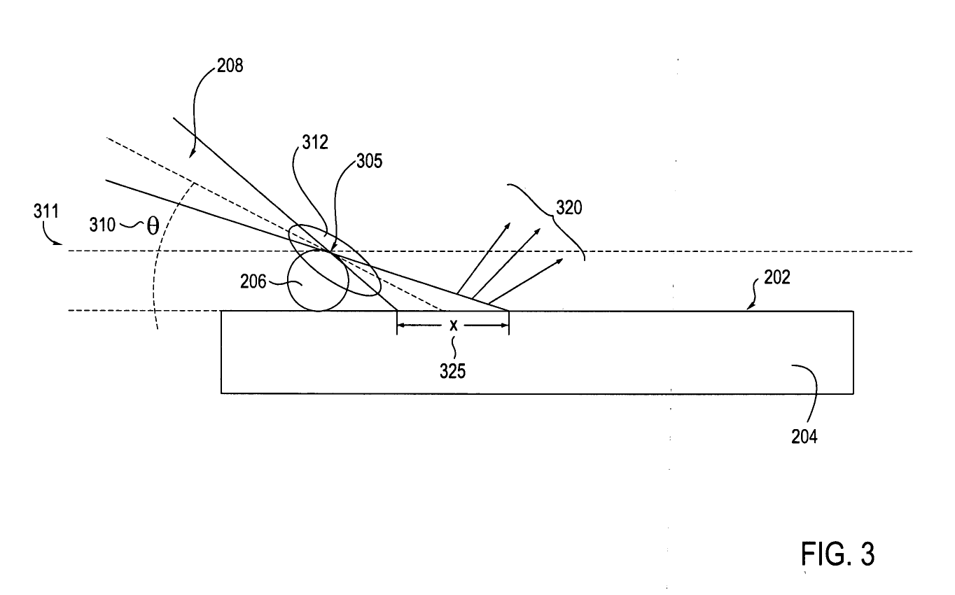

In other embodiments of the invention, several techniques may be performed during focusing of the laser beam to ensure that the underlying surface 202 experiences as little damage as possible. FIG. 3 illustrates a method of focusing the short pulse laser beam 208, according to one embodiment of the invention, to minimize, or entirely avoid, damage to the surface 202 underneath the particle defect. Referring to FIG. 3, one technique includes directing the laser beam 208 so that a focal point 305 of the laser beam contacts the particle defect at a low incidence angle 310. In one embodiment of the invention, the laser beam may be directed so that a focal point 305 of the laser beam contacts the particle defect at an angle 310 between about 5° to about 30° from the wafer surface 202. An advantage of focusing the laser at a low incidence angle 310 is that during ablation, a high energy plasma plume 312 is shifted up, and away, from the wafer surface 202. More specifically, during laser ablation, the high energy plasma plume 312 may tend to form as a result of the rapid thermal gradient increase. The high energy plume 312 has an elliptical shape and may exist in a region around the focal spot up to a distance of 10 um. When the laser beam is focused at a low incidence angle 310, however, the bottom portion of the ion plasma plume 312 is angled up, and away, from the wafer surface 202. Hence, the wafer surface 202 is spared from the potentially damaging effect of the high energy plasma plume. Another advantage to using the low incidence angle technique is that the amount of reflected energy 320 increases with a lower incidence angle, up to a critical angle beyond which all energy is reflected entirely. In the event the laser misses the particle, the low incidence angle laser beam will more likely direct less energy into the surface.

Still referring to FIG. 3, another technique to reduce damage to the underlying wafer surface 202 may include positioning the focal point 305 of the laser beam 208 to be above the wafer surface 202 at a distance approximately equivalent to the approximate radius of the particle defect. In one embodiment of the invention, the technique may include positioning the focal point 305 of the laser beam 208 to be between about 1 um to about 10 um above the wafer surface 202. An advantage of positioning the focal point 305 of the laser beam 208 at a focal plane 311 above the wafer surface 202 is so that the high energy plasma plume 312 is further away from the wafer surface 202. Another advantage of positioning the focal point of the laser beam above the wafer surface 202 is so that if the laser beam 208 happens to miss the particle defect, the projected “post-focal-point” energy, or the projected energy 320 of the laser beam after the focal point, is less when it reaches the wafer surface 202. More specifically, when the laser beam 208 moves past its focal point 305, it begins to span out, as shown in FIG. 3, into a projected area of illumination (×)325. The energy flux per unit area of the laser beam begins to decrease the more the projected area of illumination (×)325 spans out. Hence, the laser energy is spread out over a larger area of illumination (×)325 across the wafer surface 202, as shown in FIG. 3, therefore, less potential damage would occur to the wafer surface 202 if the laser beam missed the particle defect and struck the wafer surface 202. The elevated focal point 305 is also advantageous even when the laser beam does not miss the particle defect, but actually makes direct contact with, and ablates the particle. More specifically, after ablation occurs, there may be a short period of reaction time between ablation of the particle defect and turning off the laser beam. During that reaction time, the laser beam may strike the wafer surface 202 for a brief moment. However, in the same way as described above, the elevated focal point allows the projected energy to span out and reduce before striking the wafer surface 202 so that the energy flux per unit area is decreased across the area of illumination (×)325 of the wafer surface 202, reducing potential damage to the wafer surface 202.

Still referring to FIG. 3, another technique to reduce potential damage to the wafer surface 202 may include only focusing the laser upon particles with an approximate diameter of between about 1 um to about 10 um. Particles larger than 10 um may require too much explosive energy when ablated and may cause significant damage to the wafer surface 202 in the event the laser misses the particle. Particles smaller than 1 um, however, may be very difficult to pin-point accurately and ablate without undue risk to the wafer surface 202. However, it should be emphasized that particles larger than 10 um, or particles smaller than 1 um, may still be ablated according to the procedures described herein, but one must consider that the risk of damaging the underlying surface 202, however, may increase beyond the 1 um to 10 um range.

Still referring to FIG. 3, yet another technique includes only focusing the laser upon a particle that has a significant portion of its volume above the wafer surface 202.

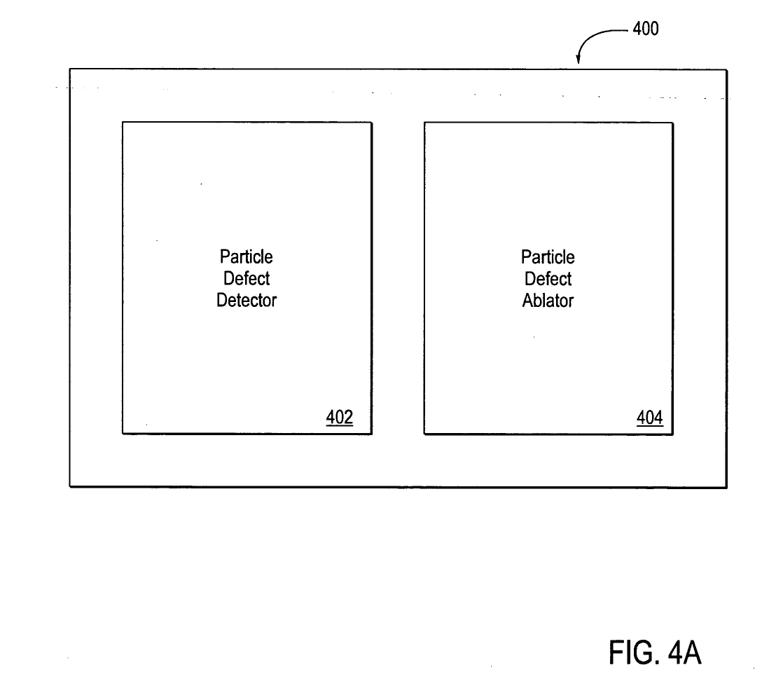

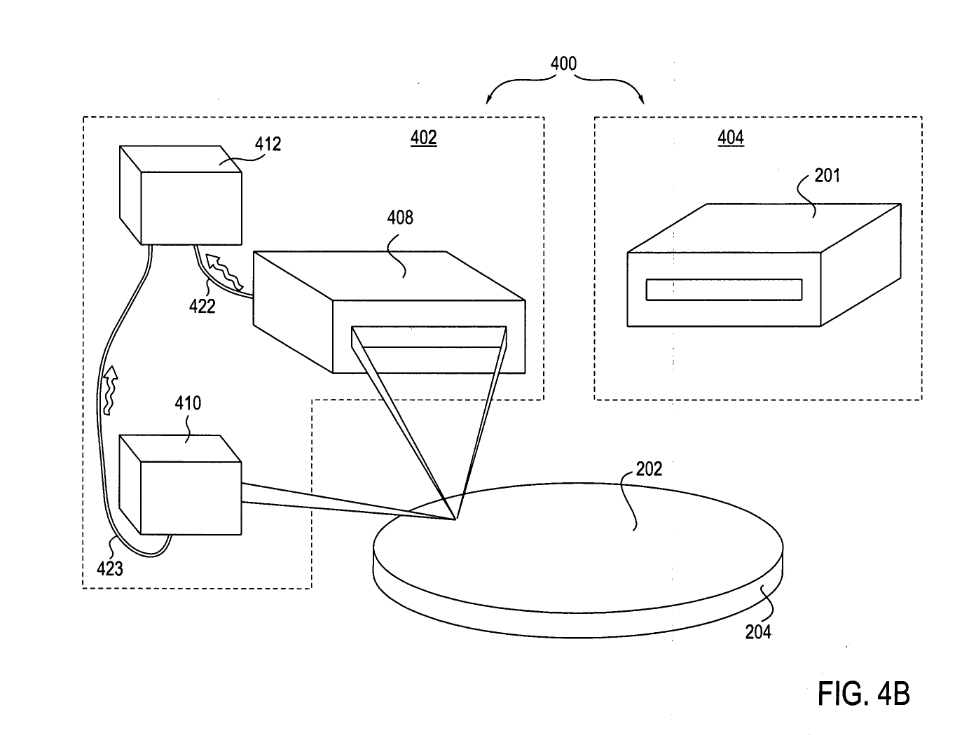

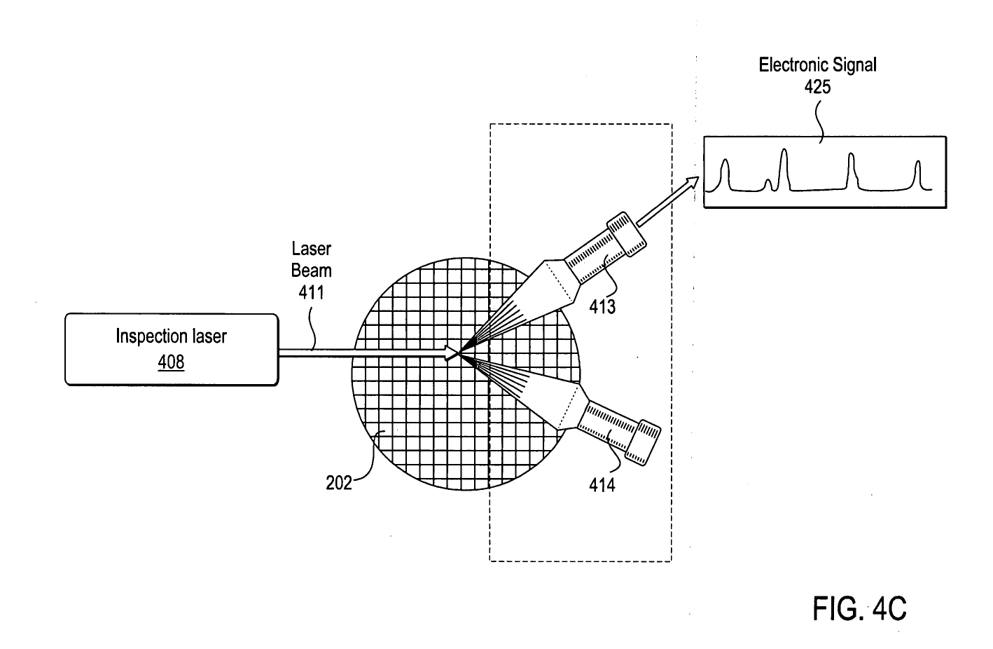

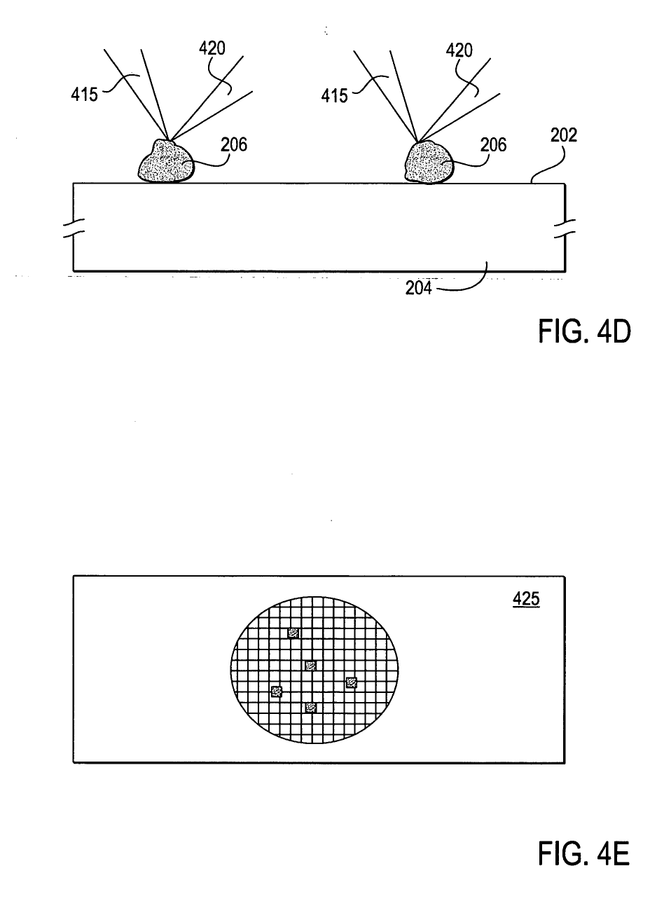

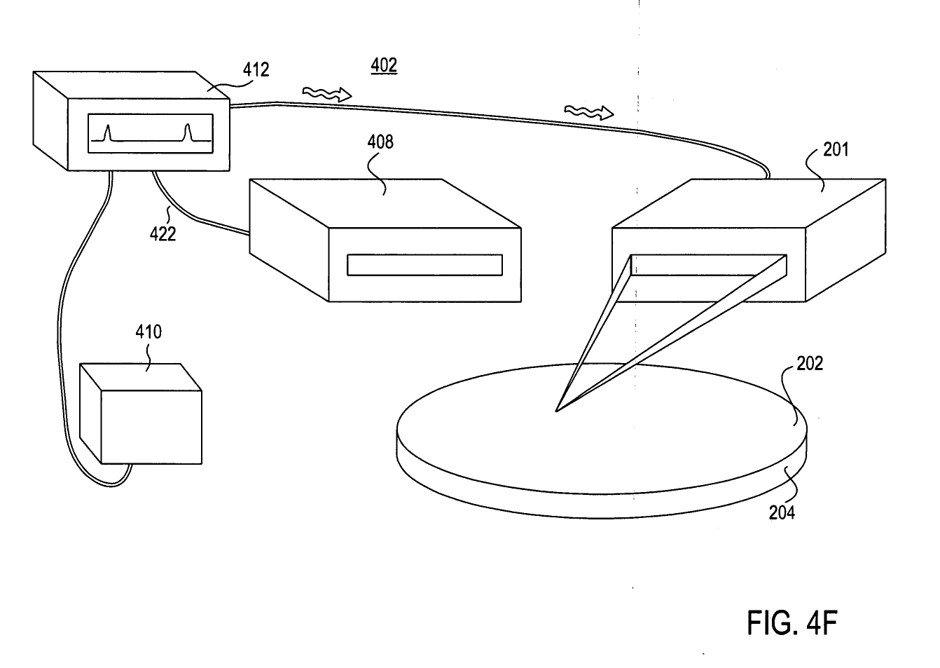

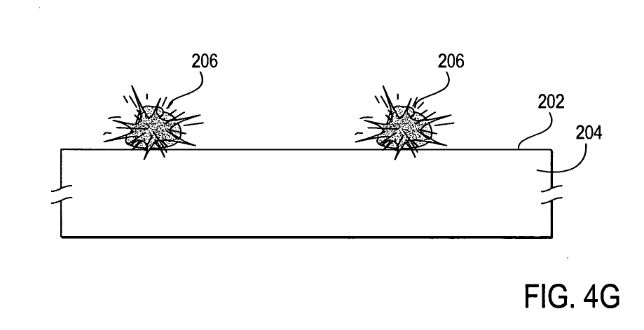

FIGS. 4A-4G illustrate a system 400 according to one embodiment of the invention. The system includes a particle defect detector 402, to detect particle defects on a wafer surface 202, and a particle defect ablator 404 to ablate the particle defects. The system 400 may be referred to as a particle defect inspection and repair tool. The particle defect detector 402 may include one of many inspection tools known and used in the semiconductor fabrication arts to inspect wafer surfaces for the purposes of quality inspection. However, until now, no known repair tools have been coupled with and used in conjunction with an inspection tool. An advantage, therefore, of embodiments of the invention described herein, is that particle defects can be detected and then eliminated (ablated) immediately after detection. Additionally, another advantage, according to other embodiments of the invention, is that particle defects can be detected and analyzed with the particle defect detector, to gather information, or electronic data, about the defects, such as the location of the defects on the wafer surface 202 and/or physical properties about the defects (size, shape, material composition, etc.). The data can then be stored in a computer memory and further processed to determine an automated ablation process specially designed based on the information gathered about the particle defects. Shortly after further processing of the data, the defects can be eliminated according to the automated ablation process.

In one embodiment of the invention, as shown in FIG. 4B, the particle defect ablator 404 may include a short pulse laser 201 that can deliver high energy, short pulsed laser beams to a surface 202 of a wafer 204. In one embodiment of the invention, as described further above, the particle defect ablator includes a femtosecond laser to provide a pulsed laser beam to the particle defects. In one embodiment of the invention, the pulsed laser beam may be operated at an approximate time frequency between about 50 fs to about 500 fs. Additionally, in one embodiment of the invention, the pulsed laser beam may be operated at an energy between about 1 uJ to about 30 uJ.

The particle defect detector 402 may include a plurality of devices, one of which may be a low-energy inspection laser 408, to detect particle defects above the wafer surface 202 and to produce signals containing data about the particle defects physical properties and location. Accompanying devices may also be employed as part of, or in conjunction with, the inspection laser 408. In one embodiment of the invention, one or more assisting devices, 410 is utilized to assist in particle detection. Hence, the particle defect detector 402, can gather information relating to the particle defect's position on the wafer surface 202 and/or the particle defect's location in relation to other structures that may exist on the wafer 204. In addition, the particle defect detector 402 (i.e., inspection laser 408 and assisting device(s), 410) may be specially configured to gather extra data other than location information, about the particles. For example, extra data may include information about the physical properties of the particle defect, such as its approximate size, shape, material composition, etc.

An example of a particle defect detector 402 using an inspection laser 408 and two assisting devices 410 is illustrated in an overhead view in FIG. 4C. The inspection laser 408 can be any low energy laser such as an argon (Ar) ion type, 480 nm wavelength, laser that operates at _{N} 75 mW of power. The inspection laser will scan across the wafer surface 202 to record defect locations. This inspection system is based on low energy laser light scattering when the laser beam 411 of the inspection laser 408 hits a defect. This light scattering is then detected by the optical detectors 413 and 414. The electronic signal 425 will be translated by the processing device 412 into a “map” of the defect locations for the short pulse laser 201 to ablate the particles.

Referring again to FIG. 4B, any data gathered about the particle defects may then be transferred as electronic signals to a processing device 412 which receives, interprets, and manipulates the data into useful machine-readable formats. The processing device 412 may include optical and/or electronic devices that are necessary to convert the signals into machine readable format. The processing device 412 may also include a computer, encompassing hardware and/or software, necessary to compute the machine readable data. Software may be utilized to manipulate the electronic data according to predetermined algorithms.

In one embodiment of the invention, the processing device 412 may create an electronic map pertaining to detected locations of the particle defects. Such an electronic map 425 (for examples see FIGS. 4C and 4E) may be referred to, more specifically herein, as a coordinate map. The particle defect ablator 404 may then utilize the coordinate map to align the short pulse laser 201 to the particle defects on the wafer surface 202 during the ablation process. Additionally, in one embodiment of the invention, the processing device 412 may create an electronic database of data pertaining to the physical properties of the particle defects, or in other words a “particle-properties” database. The particle defect ablator 404 may then utilize the particle-properties database to control power, time frequency pulsing, or other electronic functions of the short pulse laser 201.

FIGS. 4B-4G illustrate a method of utilizing the system 400, according to embodiments of the invention. In short, FIGS. 4C-4G describe (1) how the particle defect detector 402 may scan the surface 202 of a wafer 204 to gather data about location and physical properties of particle defects on the wafer 204 surface 202 and (2) how the particle defect ablator 404 may align and focus a short pulse laser 201 beam on the particle defects to ablate the particle defects. The particle defect ablator 404 may utilize the previously gathered data to align, focus, and electronically operate the short pulsed laser to ablate the particle defects according to method embodiments of the invention, such as those described previously.

As shown in FIGS. 4B-4D, the particle defect detector 402 may scan a surface 202 of a wafer 204 to gather information regarding the location and/or physical properties of the particle defects on the surface 202. The information, in the form of an optic, electronic, opto-electronic, or other electromagnetic signals, is transferred via lines 422, 423, to the processing device 412, which receives the signals and interprets, computes, or in any other way, manipulates the data into useful machine-readable formats, including electronic data bits that are readable by computer devices. The electronic data bits may be processed by a computer processor in the form of computer instructions, or stored in a computer memory.

FIG. 4E illustrates a representation of a machine-readable data object 425 (document, signal, instruction, etc.) that is computed, determined, or otherwise generated by the processing device. In an alternate embodiment of the invention, the processing device 412 may utilize the data to compute a coordinate map including numerical coordinates relating to the particle defects position on the wafer surface 202 may be generated. In another embodiment of the invention, the processing device 412 utilizes the data to compute a database of physical properties of the particle defects. The database may include information such as size, shape, and material composition of the particle defects. This information may be stored in short term memory, or long term, memory, for immediate or subsequent use.

Consequently, as shown in FIG. 4F, the particle defect ablator, or more specifically, the short pulse laser 201, may utilize the machine readable data objects (e.g., the coordinate map and the database) to locate the particle defects, then align and focus a short pulsed laser beam upon the particle defects. The particle defect ablator 201 may also utilize the data to operate various aspects of the laser, such as power, time frequency pulsing, or other electronic functions of the short pulse laser 201.

In one embodiment of the invention, aligning, focusing, and other operations of the particle defect ablator 404, may be performed automatically, by a machine, either immediately after detection, or according to a subsequent timing schedule after the data has been processed. Hence, in one embodiment of the invention, the detecting optical devices of the particle defect detector 402 may scan across the surface 202 of the wafer 204 and the ablating, short pulsed, laser beam may follow immediately thereafter to ablate the particles 206 as illustrated in FIG. 4G. On the other hand, the detecting optical devices of the particle defect detector 402 may complete a thorough scan of the surface 202 of the wafer 204, gathering data and storing the data in memory. Later, the data may be extracted from memory and processed. The processed data may then be utilized by the particle defect ablator 404 to ablate particles. Furthermore, one ordinarily skilled in the art will recognize that it may be necessary, at times, to operate the particle defect ablator 404 with some degree of manual control, as opposed to complete automation, to allow for a more carefully controlled ablation process. In one additional embodiment, the inspection and repair systems share the same optical system, which would include focusing, and navigation systems in order to accomplish the immediate repair of a defect during automated inspection. One notable advantage to the immediate ablation repair once a defect is detected, is that alignment to the defect is already attained, and the issue of stray laser energy hitting the wafer is significantly reduced.

Several embodiments of the invention have thus been described. However, those ordinarily skilled in the art will recognize that the invention is not limited to the embodiments described, but can be practiced with modification and alteration within the spirit and scope of the appended claims that follow.

1. An apparatus, comprising:
a short pulse laser to remove at least one particle defect on a wafer surface.

2. The apparatus of claim 1, wherein the short pulse laser is a femtosecond laser.

3. The apparatus of claim 1, wherein the short pulse laser has a pulse period of about 50 femtoseconds (fs) to about 500 fs.

4. The apparatus of claim 1, wherein the at least one particle defect has an approximate diameter of about 1 to about 10 micrometers (μm).

5. The apparatus of claim 1, wherein the at least one particle defect has a significant portion of its volume above the wafer surface.

6. The apparatus of claim 1, wherein the short pulse laser is to exert an energy of between about 1 to about 30 microJules (uJ) per pulse.

7. A method, comprising:
focusing a short pulse laser beam onto a particle defect on a wafer surface; and
ablating the particle defect with the short pulse laser beam.

8. The method of claim 7, wherein ablating is to cause the particle defect to undergo explosive evaporation.

9. The method of claim 7, wherein ablating is to cause the thermal gradient in the particle defect to increase rapidly causing substantial internal stress within the particle defect causing explosive fracture.

10. The method of claim 7, wherein focusing is to direct the laser beam so that a focal point of the laser beam contacts the particle defect at a low incidence angle.

11. The method of claim 7, wherein focusing is to direct the laser beam so that a focal point of the laser beam contacts the particle defect at an angle between about 5° to about 30° from the wafer surface.

12. The method of claim 7, wherein focusing is to position a focal point of the laser beam to be above the wafer surface at a distance approximately equivalent to the approximate radius of the particle defect.

13. The method of claim 7, wherein focusing is to position a focal point of the laser beam to be between about 1 um to about 10 um above the wafer surface.

14. The method of claim 7, wherein the particle defect has an approximate diameter of between about 1 um to about 10 um.

15. The method of claim 7, wherein the particle defect has a significant portion of its volume above the wafer surface.

16. The method of claim 7, further comprising:
scanning the surface of the wafer to gather data about the location and physical properties of the particle defects; and
aligning the laser beam according to the data.

17. A system, comprising:
a particle defect detector to detect particle defects on a wafer surface; and
a particle defect ablator including a short pulse laser to ablate the particle defects.

18. The system of claim 17, wherein the particle defect detector includes a low energy laser to detect the particle defects above the wafer surface and produce signals containing data about the particle defects physical properties and location.

19. The system of claim 17, wherein the particle defect detector includes a processing device to receive the signals and utilize the data.

20. The system of claim 17, wherein the processing device is to utilize the data to compute a coordinate map of the particle defects, and wherein the particle defect ablator is to utilize the coordinate map to align the short pulse laser to the particle defects on the wafer surface.

21. The system of 17, wherein the processing device is to utilize the data to compute a particle-properties database containing physical properties about the particle defect and wherein the particle defect ablator is to utilize the particle-properties database to control power, time frequency pulsing, or other electronic functions of the short pulse laser.

22. The system of claim 17, wherein the particle defect ablator includes a femtosecond laser.

23. The system of claim 17, wherein the particle defect ablator is to provide a pulsed laser beam to the particle defect, the pulsed laser beam having an approximate time frequency between about 50 fs to about 500 fs.

24. The system of claim 17, wherein the particle defect ablator is to provide a pulsed laser beam to the particle defect, the pulsed laser beam having an energy between about 1 uJ to about 30 uJ.

25. A method, comprising:
scanning the surface of a wafer to gather data about location and physical properties of particle defects on the wafer surface; and
aligning and focusing a short pulse laser beam on particle defects to ablate the particle defects, the aligning and focusing being performed based on the data.

26. The method of claim 17, wherein aligning and focusing is done automatically.

27. The method of claim 17, further comprising:
computing a coordinate map of particle defects according to the data; and
utilizing the coordinate map to position a focal point of a laser beam upon the particle defects.

28. The method of claim 17, further comprising:
computing a database of physical properties of the particle defects according to the data; and
utilizing the database of physical properties to control power, time frequency pulsing, or other electronic functions of the short pulse laser.

29. The method of claim 17, further comprising:
computing a coordinate map of the location of particle defects based on the data;
computing a database of physical properties of the particles defects based on the data; and
storing the coordinate map and database in memory to be utilized subsequently to ablate the particles defects.
